(19) United States
(12) Patent Application Publication
(10) Pub. No.: US 2024/0332221 A1
(43) Pub. Date: Oct. 3, 2024

(54) SEMICONDUCTOR PACKAGE

(71) Applicant: Samsung Electronics Co., Ltd., Suwon-si (KR)

(72) Inventors: Seungyoung AHN, Daejeon (KR); Seonghi LEE, Daejeon (KR); Hyunwoong KIM, Daejeon (KR); Jiseong KIM, Daejeon (KR)

(73) Assignees: Samsung Electronics Co., Ltd., Suwon-si (KR); KOREA ADVANCED INSTITUTE OF SCIENCE AND TECHNOLOGY, Daejeon (KR)

(21) Appl. No.: 18/422,406

(22) Filed: Jan. 25, 2024

(30) Foreign Application Priority Data
Mar. 30, 2023 (KR) 10-2023-0041905
Jun. 12, 2023 (KR) 10-2023-0074628

(51) Int. Cl. H01L 23/64; H01L 23/00; H01L 23/498; H01L 23/538; H01L 25/065; H10B 80/00

(52) U.S. Cl. CPC H01L 23/64; H01L 23/49816; H01L 23/49838; H01L 23/538; H01L 24/16; H01L 24/17; H01L 25/0652; H01L 25/0657; H10B 80/00; H01L 2224/16148; H01L 2224/16227; H01L 2224/16238; H01L 2224/1703; H01L 2225/06513; H01L 2225/06517; H01L 2225/06541; H01L 2924/1431; H01L 2924/1435

(57) ABSTRACT

A semiconductor package includes a package substrate, an interposer die disposed on the package substrate, semiconductor chips disposed on the interposer die and electrically connected to the package substrate via the interposer die, first connection bumps electrically connecting the semiconductor chips to the interposer die, second connection bumps electrically connecting the interposer die to the package substrate, and third connection bumps disposed below the package substrate, wherein the interposer die includes spiral matching structures adjacent to upper portions of the second connection bumps, and the package substrate includes trace-shaped matching structures adjacent to lower portions of the second connection bumps.

### CROSS-REFERENCE TO RELATED APPLICATION(S)

This application claims benefit of priority to Korean Patent Application No. 10-2023-0074628 on Jun. 12, 2023 and Korean Patent Application No. 10-2023-0041905 filed on Mar. 30, 2023 in the Korean Intellectual Property Office, the disclosures of which are incorporated herein by reference in their entirety.

### BACKGROUND

Example embodiments of the present disclosure relate to semiconductor packages.

When semiconductor chips having high-performance provided in a semiconductor package communicate with an external device through connection bumps, signal loss and signal integrity degradation may occur, due to impedance mismatching caused by connection bumps. Accordingly, it may be necessary to develop impedance matching elements for compensating for impedance mismatching in a semiconductor package.

### SUMMARY

Some example embodiments of the present disclosure provide semiconductor devices including a stable contact plug having reliability.

According to an example embodiment in the present disclosure, a semiconductor package includes a package substrate, an interposer die on the package substrate, semiconductor chips, on the interposer die, the interposer die electrically connected to the package substrate via the interposer die, first connection bumps electrically connecting the semiconductor chips to the interposer die, second connection bumps electrically connecting the interposer die to the package substrate, and third connection bumps disposed below the package substrate, wherein the interposer die includes spiral matching structures adjacent to upper portions of the second connection bumps, and the package substrate includes trace-shaped matching structures adjacent to a lower portion of the second connection bumps.

According to an example embodiment of the present disclosure, a semiconductor package includes a package substrate including trace-shaped matching structures and a wiring circuit, the trace-shaped matching structures being adjacent to an upper surface of the package substrate, the wiring circuit electrically connected to the trace-shaped matching structures, an interposer die on the upper surface of the package substrate, the interposer die including spiral matching structures adjacent to a lower surface of the interpose die, semiconductor chips on the interposer die, first connection bumps electrically connecting the semiconductor chips to the interposer die, and second connection bumps electrically connecting the spiral matching structures of the interposer die to the trace-shaped matching structures of the package substrate, wherein a line width of each of the spiral matching structures is less than or equal to a line width of each of the trace-shaped matching structures, and a line width of each of the trace-shaped matching structures is smaller than a line width of the wiring circuit.

According to an example embodiment of the present disclosure, a semiconductor package includes a package substrate including first matching structures and a wiring circuit electrically connected to the first matching structures, an interposer die on the package substrate, the interposer die including second matching structures, semiconductor chips on the interposer die, first connection bumps electrically connecting the semiconductor chips to the interposer die, and second connection bumps electrically connecting the first matching structures of the package substrate to the second matching structures of the interposer die, wherein the first matching structures and the second matching structures have different shapes to compensate for mismatching of impedance caused by the second connection bumps.

### BRIEF DESCRIPTION OF DRAWINGS

The above and other aspects, features, and advantages in the example embodiments will be more clearly understood from the following detailed description, taken in combination with the accompanying drawings, in which:

FIG. 1A is a cross-sectional diagram illustrating a semiconductor package according to an example embodiment of the present disclosure;

FIG. 1B is a plan diagram illustrating a semiconductor package according to an example embodiment of the present disclosure;

FIG. 2A is a perspective diagram illustrating first and second impedance matching structures according to an example embodiment of the present disclosure;

FIG. 2B is a plan diagram illustrating a first impedance matching structure according to an example embodiment of the present disclosure;

FIG. 2C is a plan diagram illustrating a second impedance matching structure according to an example embodiment of the present disclosure;

FIG. 3 is a perspective diagram illustrating first and second impedance matching structures according to an example embodiment of the present disclosure;

FIG. 4 is a perspective diagram illustrating first and second impedance matching structures according to an example embodiment of the present disclosure;

FIG. 5 is a cross-sectional diagram illustrating a semiconductor package according to an example embodiment of the present disclosure;

FIG. 6 is a cross-sectional diagram illustrating a semiconductor package according to an example embodiment of the present disclosure;

FIGS. 7A and 7B are cross-sectional diagrams illustrating characteristic parameters of a signal input to and output from a semiconductor package according to an example embodiment of the present disclosure;

FIGS. 8 and 9 are diagrams illustrating a mixed mode S parameters of a signal input to and output by a semiconductor package according to an example embodiment of the present disclosure;

FIG. 10 is a diagram illustrating the amount of impedance change of a signal input to and output by a semiconductor package according to an example embodiment of the present disclosure; and

FIG. 11 is a diagram illustrating a TDR result of a signal input to and output by a semiconductor package according to an example embodiment of the present disclosure.

### DETAILED DESCRIPTION

Hereinafter, some example embodiments of the present disclosure will be described as follows with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

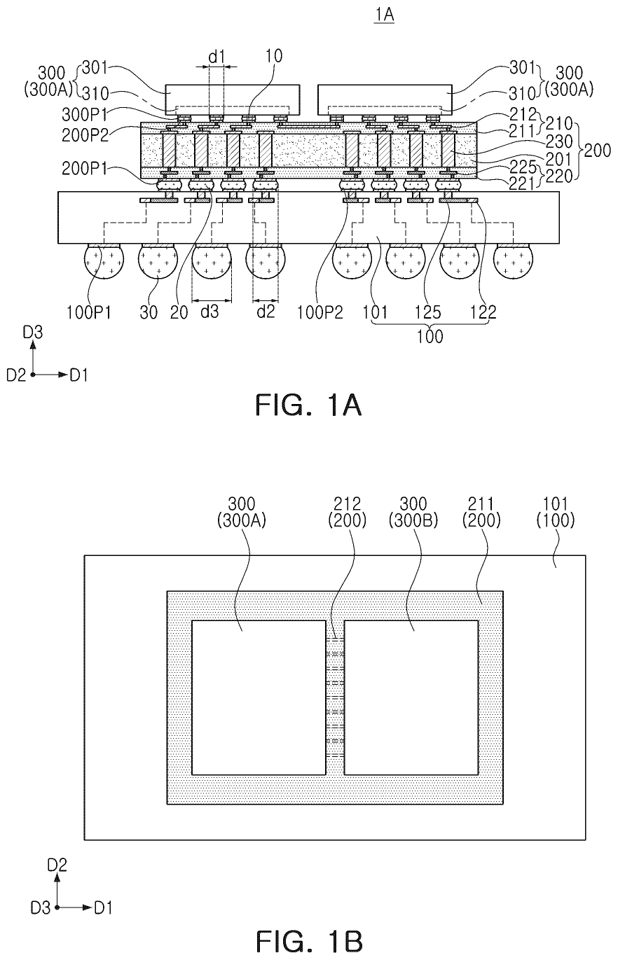

FIG. 1A is a cross-sectional diagram illustrating a semiconductor package according to an example embodiment. FIG. 1B is a plan diagram illustrating a semiconductor package according to an example embodiment.

Referring to FIGS. 1A and 1B, a semiconductor package 1A in an example embodiment may include a package substrate 100, an interposer die 200, and at least one semiconductor chip 300.

The package substrate 100 may be configured as a substrate for a semiconductor package including a printed circuit board PCB, a ceramic substrate, a glass substrate, and a tape wiring board. For example, the package substrate 100 may be implemented as a one-sided PCB, a double-sided PCB or a multilayer PCB. The package substrate 100 may include a substrate body 101, a wiring circuit 122, and first impedance matching structures (hereinafter, first matching structures 125). The package substrate 100 may include a lower pad 100P1 disposed on a lower surface of the substrate body 101, and an upper pad 100P2 disposed on an upper surface of the substrate body 101. A lower pad 100P1 and an upper pad 100P2 may include at least one metal material among aluminum (Al), copper (Cu), nickel (Ni), tungsten (W), platinum (Pt) and gold (Au), but example embodiments thereof are not limited thereto.

The substrate body 101 may include an insulating material for electrically and physically protecting the wiring circuit 122 and the first matching structures 125. For example, the insulating material may include a thermosetting resin such as epoxy resin, a thermoplastic resin such as polyimide. For example, the insulating material may include a material including inorganic filler and/or glass fiber such as prepreg, Ajinomoto build-up film (ABF), or frame retardant 4 (FR4).

The wiring circuit 122 may electrically connect the lower pad 100P1 to the upper pad 100P2. The wiring circuit 122 may include a conductive pattern (not illustrated) and a conductive via (not illustrated) forming an electrical connection path. The wiring circuit 122 may include at least one metal from among Copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), carbon (C) or an alloy of two or more such metals.

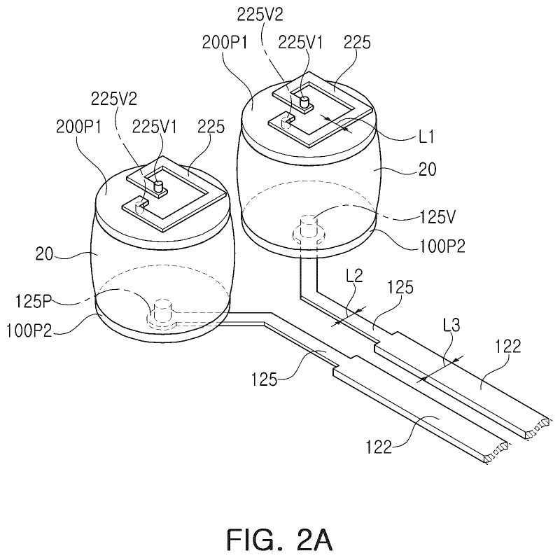

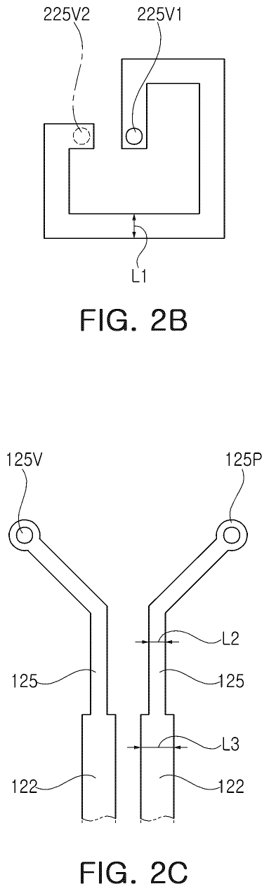

The first matching structures 125 may be adjacent to an upper surface of the package substrate 100 and may electrically connect the upper pad 100P2 to the wiring circuit 122. The first matching structures 125 may have a shape to compensate for impedance mismatching caused by the second connection bumps 20. Each of the first matching structures 125 may have a trace shape having a line width smaller than that of the wiring circuit 122 (see FIG. 2A). In some example embodiments, the first matching structures 125 may be referred to as “trace-shaped matching structures.”

The interposer die 200 may include a semiconductor substrate 201, an upper circuit layer 210, a lower circuit layer 220, and through-vias 230. The interposer die 200 may include a lower pad 200P1 and an upper pad 200P2. The lower pad 200P1 and the upper pad 200P2 may include at least one metal material from among, for example, aluminum (Al), copper (Cu), nickel (Ni), tungsten (W), platinum (Pt) and gold (Au), but example embodiments thereof are not limited thereto.

The semiconductor substrate 201 may include semiconductor elements such as silicon and germanium, or a compound semiconductor such as silicon carbide (SiC), gallium arsenide (GaAs), indium arsenide (InAs), and indium phosphide (InP).

The upper circuit layer 210 may be disposed on an upper end of the semiconductor substrate 201 and may include an interlayer insulating layer 211, and an upper connection circuit 212 including multiple pattern layers and contact vias. The interlayer insulating layer 211 may include silicon oxide or silicon nitride. The upper connection circuit 212 may interconnect the semiconductor chips 300 or may connect the semiconductor chips 300 to through-vias 230.

The upper connection circuit 212 may form a host interface (HIF) interconnecting the semiconductor chips 300. The host interface (HIF) may use various standards, such as parallel advanced technology attachment (PATA) standard, serial advanced technology attachment (SATA) standard, SCSI standard, PCI Express (PCIe) standard, universal frame system (UFS) standard, universal serial bus (USB) standard, or thunderbolt standard. The SATA standard may encompass the entirety of SATA series standards such as SATA-1, SATA-2, SATA-3, e-SATA (external SATA). The PCIe standard may include PCIe 1.0, and also the entirety of PCIe family standards including PCIe 2.0, PCIe 2.1, PCIe 3.0, PCIe 4.0. The SCSI standard may encompass the entirety of SCSI family standards, such as parallel SCSI, serial bonding SA-SCSI (SAS), and iSCSI.

The lower circuit layer 220 may be disposed on a lower portion of the semiconductor substrate 201, and may include an interlayer insulating layer 221 and second impedance matching structures (hereinafter, second matching structures 225). In some example embodiments, the lower circuit layer 220 may further include a lower connection circuit (not illustrated) connecting the second matching structures 225 to the through-vias 230. The interlayer insulating layer 221 and a lower connection circuit (not illustrated) of the lower circuit layer 220 may include a material similar to that of the interlayer insulating layer 211 and the upper connection circuit 212 of the upper circuit layer 210 described above.

The second matching structures 225 may be adjacent to a lower surface of the semiconductor substrate 201 and may electrically connect the lower pad 200P1 to the through-vias 230. The second matching structures 225 may have a shape to compensate for impedance mismatching caused by the second connection bumps 20. Each of the second matching structures 225 may have a single-layer or multilayer spiral shape (see FIG. 2A). In some example embodiments, the second matching structures 225 may be referred to as “spiral matching structures.”

The elements for impedance mismatching compensation may be provided on and below the second connection bumps 20, respectively. The first matching structures 125 and the second matching structures 225 may be formed in different shapes in consideration of density of circuits disposed above and below the second connection bumps 20, respectively, thereby more effectively matching impedance of the transmission line passing through the second connection bumps 20, as described below in greater detail with reference to FIGS. 2A to 2C.

The through-vias 230 may be configured as a through silicon via (TSV) penetrating the semiconductor substrate 201 in the vertical direction D3. The through-vias 230 may provide an electrical path connecting the lower pad 200P1 to the upper pads 200P2. The through-via 230 may include a conductive plug and a barrier film surrounding the conductive plug. The conductive plug may include a metal material such as tungsten (W), titanium (Ti), aluminum (Al), or copper (Cu). The conductive plug may be formed by a plating process, a PVD process, or a CVD process. The barrier film may include an insulating barrier film and/or a conductive barrier film. The insulating barrier film may be formed of an oxide film, a nitride film, a carbide film, a polymer, or a combination thereof. The conductive barrier film may include a metal compound such as tungsten nitride (WN), titanium nitride (TiN), or tantalum nitride (TaN). The barrier film may be formed by a PVD process or a CVD process.

The semiconductor chip 300 may be electrically connected to the package substrate 100 through the through-via 230 of the interposer die 200. The semiconductor chip 300 may include a semiconductor substrate 301 and an integrated circuit region 310. The semiconductor substrate 301 may include a material similar to that of the semiconductor substrate 201 of the interposer die 200 described above. The integrated circuit region 310 may include a logic circuit such as a central processor (CPU), graphics processor (GPU), field programmable gate array (FPGA), application processor (AP), digital signal processor, cryptographic processor, microprocessor, microcontroller, analog-to-digital converter, application-specific IC (ASIC), and/or a volatile memory such as dynamic RAM (DRAM), static RAM (SRAM), and a non-volatile memory such as phase change RAM (PRAM), magnetic RAM (MRAM), resistive RAM (RRAM), and flash memory.

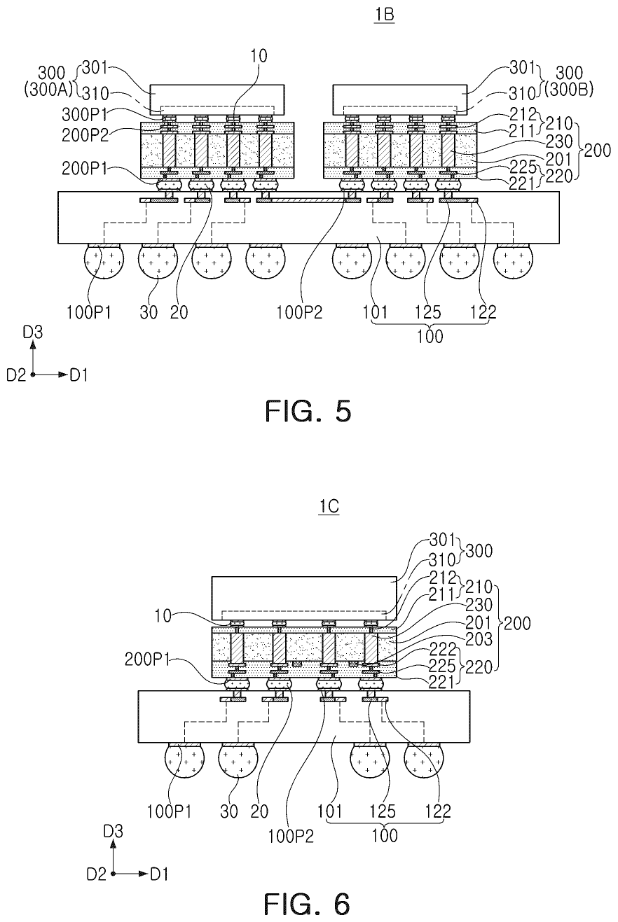

The semiconductor chip 300 may include a plurality of semiconductor chips 300 disposed on the interposer die 200. For example, the semiconductor chip 300 may include a first semiconductor chip 300A and a second semiconductor chip 300B disposed side by side on the interposer die 200, but example embodiments thereof are not limited thereto. In some example embodiments, the semiconductor chips 300 may be vertically stacked on the interposer die 200 (see FIG. 5). The first semiconductor chip 300A and the second semiconductor chip 300B may include different types of semiconductor chips, but example embodiments thereof are not limited thereto. For example, the first semiconductor chip 300A may include a logic chip, and the second semiconductor chip 300B may include a memory chip. In this case, the second semiconductor chip 300B may be provided as a high-capacity memory device such as a high bandwidth memory (HBM). The number of semiconductor chips 300 may be greater than the example illustrated in the drawing.

Also, the semiconductor package 1A may include connection bumps 10, 20, and 30 for electrical connection between the package substrate 100, the interposer die 200, and the semiconductor chip 300. The connection bumps 10, 20, and 30 may include tin (Sn), indium (In), bismuth (Bi), antimony (Sb), copper (Cu), silver (Ag), zinc (Zn), lead (Pb) and/or alloys thereof (e.g., Sn—Ag—Cu). The connection bumps 10, 20, and 30 may include, for example, first connection bumps 10 electrically connecting the semiconductor chip 300 to the interposer die 200, second connection bumps 20 electrically connecting the interposer die 200 to the package substrate 100, and third connection bumps 30 disposed on a lower surface of the package substrate 100 and configured to be connected to an external device (e.g., a main board and a motherboard). The second connection bumps 20 may have a second width D2 greater than the first width D1 of the first connection bumps 10. The third connection bumps 30 may have a third width D3 greater than or equal to the second width D2 of the second connection bumps 20. The first width D1 may be configured to be about 30 μm or less, for example, in a range of about 20 μm to about 30 μm. The second width D2 may be configured to be about 150 μm or less, for example, in a range of about 150 μm to about 70 μm. The third width D3 may be configured to be about 600 μm or less, for example, in a range of about 600 μm to about 300 μm. However, the first width D1, the second width D2, and the third width D3 are not limited to the above numerical range.

In some example embodiments, to compensate for impedance reduction caused by the connection bumps 10, 20, and 30 disposed in multiple stages and forming the signal transmission path, the above-described impedance matching elements ‘125’ and ‘225’ may be provided above and below the bumps (e.g., the second connection bumps 20), respectively. Thus, mismatching of target impedance caused by intermediate bumps (e.g., second connection bumps 20) may be compensated for and signal integrity of semiconductor package 1A may improve. Hereinafter, a coupling relationship between the second connection bumps 20 and the first and second impedance matching structures 125 and 225 will be described in greater detail with reference to FIGS. 2A to 2C.

FIG. 2A is a perspective diagram illustrating first and second impedance matching structures 125 and 225 according to an example embodiment. FIG. 2B is a plan diagram illustrating a first impedance matching structure 125 according to an example embodiment. FIG. 2C is a plan diagram illustrating a second impedance matching structure 225 according to an example embodiment.

Referring to FIGS. 2A, 2B, and 2C, the first matching structures 125 and the second matching structures 225 may be configured to compensate for impedance mismatching caused by the second connection bumps 20 (e.g., to reduce signal delay). The first matching structures 125 formed in the package substrate 100 having a relatively low circuit density may be configured as trace-shaped matching structures. A line width and a length of the trace-shaped matching structures may be adjusted according to an impedance compensation value. The second matching structures 225 formed in the interposer die 200 having relatively high circuit density may be configured as spiral matching structures. The line width of the spiral matching structures, a spacing therebetween, and the number of the spiral matching structures may be adjusted according to the impedance compensation value.

The first matching structures 125 may be disposed adjacent to a lower portion of the second connection bumps 20. The second matching structures 225 may be disposed adjacent to an upper end of the second connection bumps 20. The second connection bumps 20 may electrically connect the first matching structures 125 to the second matching structures 225.

Each of the first matching structures 125 may have one end electrically connected to the second connection bumps 20 and the other end electrically connected to the wiring circuit 122 of the package substrate 100. The package substrate 100 may include upper pads 100P2 in contact with a lower portion of the second connection bumps 20, and a connection via 125V connecting the upper pad 100P2 to the pad portion 125P of one end of each of the first matching structures 125. In an example embodiment, the wiring circuit 122 may include a conductive pattern in contact with the other end of the first matching structures 125 and having a line width L3.

Each of the second matching structures 225 may have one end electrically connected to the second connection bumps 20 and the other end electrically connected to a through-via 230 of the interposer die 200 or a lower connection circuit (not illustrated). The interposer die 200 may include a connection via 225V1 electrically connecting the second matching structures 225 to the through-via 230, lower pads 200P1 in contact with an upper end of the second connection bumps 20, and a connection via 225V2 connecting the lower pad 200P1 to the second matching structures 225.

The first matching structures 125 may be formed to have a line width L2 smaller than the line width L3 of the wiring circuit 122. The line width L1 of each of the second matching structures 225 may be smaller than or equal to the line width L2 of each of the first matching structures 125. The line width L1 of each of the second matching structures 225 may be in the range of about 1 μm to about 20 μm, for example, in the range of about 1 μm to about 15 μm, or about 1 μm to about 10 μm. The line width L2 of each of the first matching structures 125 may be in the range of about 5 μm to about 30 μm, for example, in the range of about 5 μm to about 25 μm, about 8 μm to about 25 μm, or about 8 μm to about 20 μm. The line width L3 of the wiring circuit 122 may be in the range of about 10 μm to about 50 μm, for example, about 10 μm to about 50 μm, about 20 μm to about 50 μm, or about 20 μm to about 30 μm. However, the above-mentioned numerical range is provided to represent the relative size relationship between the line widths L1, L2, and L3, and may be configured to be beyond the above-mentioned numerical range to obtain the target impedance.

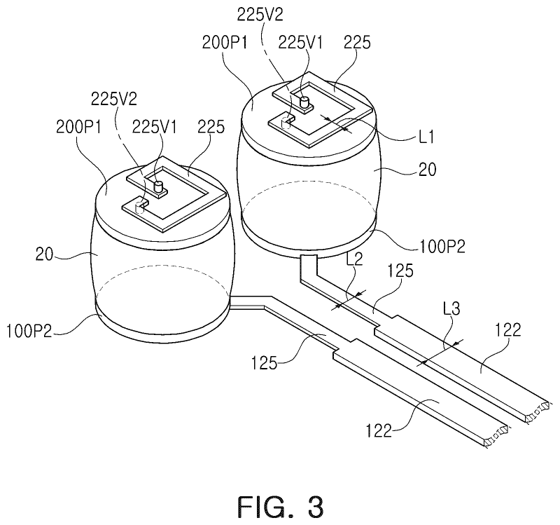

FIG. 3 is a perspective diagram illustrating first and second impedance matching structures 125 and 225 according to an example embodiment.

Referring to FIG. 3, the first matching structures 125 in the example embodiment may be configured the same as or similar to the example described with reference to FIGS. 1A to 2, other than the configuration in which the first matching structures 125 may be directly connected to one side of the upper pad 100P2 of the package substrate 100. An upper surface of the upper pad 100P2 of the package substrate 100 may be in contact with a lower portion of the second connection bumps 20. The first matching structures 125 for impedance matching may be extended on one side of the upper pad 100P2 of the package substrate 100. The first matching structures 125 may be variously modified according to the process of manufacturing the package substrate 100 or the shape of the package substrate 100 as described above.

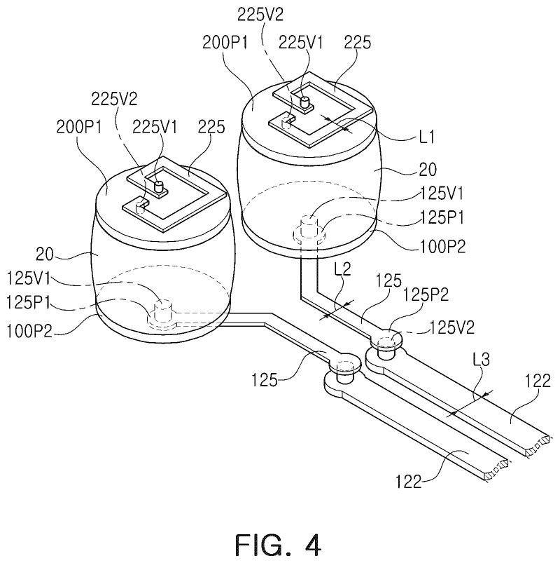

FIG. 4 is a perspective diagram illustrating first and second impedance matching structures 125 and 225 according to an example embodiment.

Referring to FIG. 4, the first matching structures 125 in the example embodiment may be configured the same as or similar to the example described with reference to FIGS. 1A to 2, other than the configuration in which the first matching structures 125 are disposed on a level higher than a level of the wiring circuit 122 of the package substrate 100. The wiring circuit 122 of the package substrate 100 may be disposed below the first matching structures 125. Each of the first matching structures 125 may have one end electrically connected to the second connection bumps 20 and the other end electrically connected to the wiring circuit 122 of the package substrate 100. The pad portion 125P1 of the one end of the first matching structures 125 may be connected to an upper pad 100P2 of the package substrate 100 through a connection via 125V1. The pad portion 125P2 of the other end of the first matching structures 125 may be connected to the wiring circuit 122 through the connection via 125V2. The first matching structures 125 may be variously modified according to the process of manufacturing the package substrate 100 or the shape of the package substrate 100 as described above.

FIG. 5 is a cross-sectional diagram illustrating a semiconductor package according to an example embodiment.

Referring to FIG. 5, the semiconductor package 1B in an example embodiment may be configured the same as or similar to the example described with reference to FIGS. 1A to 4 other than the configuration in which the first semiconductor chip 300A and the second semiconductor chip 300B are interconnected through the wiring circuit 122 of the package substrate 100. The first semiconductor chip 300A and the second semiconductor chip 300B may be mounted on the corresponding interposer dies 200, respectively. Each of the interposer dies 200 may be electrically connected to the package substrate 100. The wiring circuit 122 of the package substrate 100 may provide a channel for data communication between the first semiconductor chip 300A and the second semiconductor chip 300B.

FIG. 6 is a cross-sectional diagram illustrating a semiconductor package according to an example embodiment.

Referring to FIG. 6, a semiconductor package 1C in an example embodiment may be configured the same as or similar to the example described with reference to FIGS. 1A to 5, other than the configuration in which the interposer die 200 may include an integrated circuit. The interposer die 200 may further include individual devices 203 formed on an active surface of the semiconductor substrate 201 and a lower connection circuit 222 electrically connected to the individual devices 203 in the lower circuit layer 220 and forming an integrated circuit. The individual devices 203 may include a Field Effect Transistor (FET) such as a planar FET and FinFET, flash memory, a memory device such as DRAM, SRAM, EEPROM, PRAM, MRAM, FeRAM, and RRAM, a logic device such as AND, OR, and NOT, or various active and/or passive elements such as system LSI, CIS, and MEMS.

The semiconductor chip 300 may be electrically connected to the integrated circuit and the package substrate 100 of the interposer die 200 through the through-via 230 of the interposer die 200. The number of the semiconductor chip 300 may be configured to be greater than the example illustrated in the drawings. The semiconductor chips (not illustrated) may be vertically stacked on the interposer die 200 and may be electrically connected to each other through a through silicon via (TSV). In some example embodiments, the semiconductor chip 300 may include a different type of integrated circuit from that of the interposer die 200. For example, the interposer die 200 may include a logic circuit, and the semiconductor chip 300 may include a memory chip.

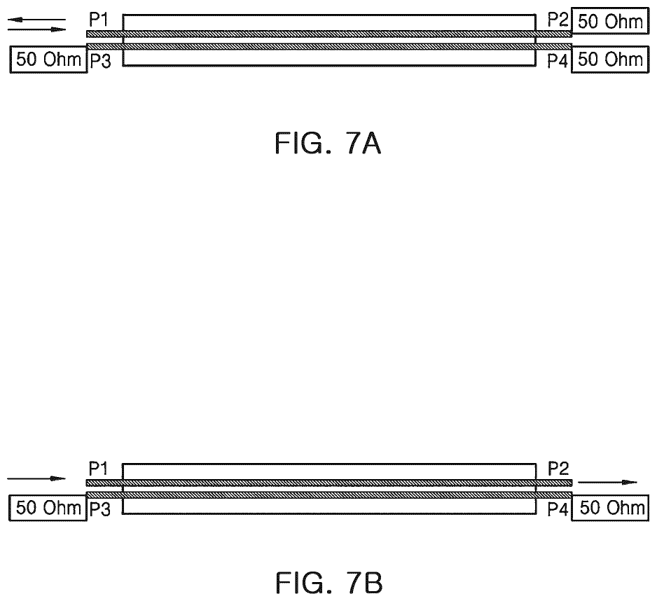

FIGS. 7A and 7B are cross-sectional diagrams illustrating characteristic parameters (S parameters) of a signal input to and output from a semiconductor package according to an example embodiment. In FIGS. 7A and 7B, each of ports P1-P4 may be configured as an input terminal or an output terminal through which signals are input and output.

Referring to FIG. 7A, the S11 parameter representing the return loss may be configured to measure a magnitude of a signal which may be input to a desired (or alternatively, predetermined) input terminal, for example, the P1 port, which is a transmission line and may return to an input terminal of the same line, that is, the P1 port. The S11 parameter may be configured to indicate how well the transmission line is matched to a target impedance, for example, 50Ω.

Referring to FIG. 7B, the S21 parameter representing insertion loss may be configured to measure a magnitude of a signal in which a signal is input to a transmission line through a desired (or alternatively, predetermined) input terminal, for example, P1 port, and may pass through an output terminal of the same line, that is, the P2 port. Insertion loss may indicate the ability of a transmission line. Insertion loss may exhibit the transmitted signal integrity and a bandwidth of the connection portion.

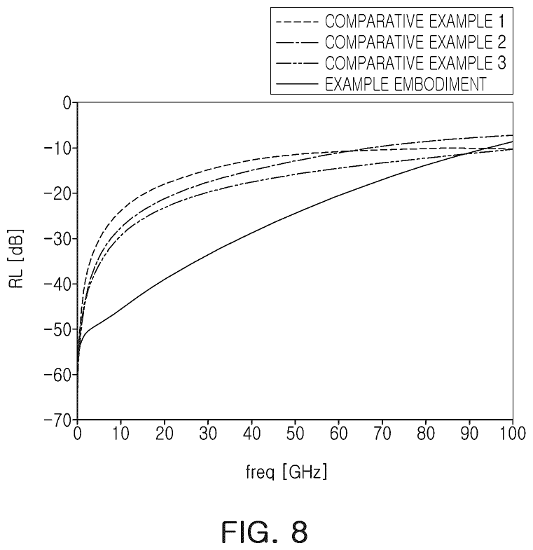

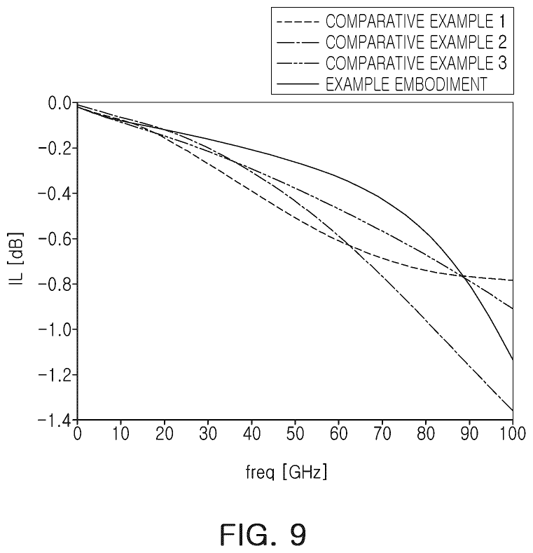

FIGS. 8 and 9 are diagrams illustrating a mixed mode S parameters of a signal input to and output from a semiconductor package according to an example embodiment. FIG. 8 may be a graph obtained by simulating an SDD11 parameter of a signal input to and output from a transmission line passing through second connection bumps 20 in semiconductor package 1A in an example embodiment. FIG. 9 may be a graph obtained by simulating an SDD21 parameter of a signal input to and output from a transmission line passing through the second connection bumps 20 in the semiconductor package 1A in an example embodiment.

In FIGS. 8 and 9, in comparative example 1, the first and second matching structures 125 and 225 were not applied. In comparative example 2, only the second matching structures 225 of the interposer die 200 were applied. In comparative example 3, only the first matching structures 125 of the package substrate 110 were applied.

Referring to FIG. 8, it is indicated that return loss RL in the example embodiment was smaller (an absolute value was greater) than the return loss RL of each of comparative example 1, comparative example 2, and comparative example 3 in the overall frequency range.

Referring to FIG. 9, the insertion loss IL in the example embodiment was greater (the absolute value was smaller) than the insertion loss IL of each of comparative example 1, comparative example 2, and comparative example 3 in the frequency range of about 20 GHz to about 90 GHz.

As indicated above, when elements for impedance matching are disposed in both directions of the second connection bumps 20, the impedance matching effect of signals input to and output from the transmission line passing through the second connection bumps 20 may be improved.

FIG. 10 is a diagram illustrating the amount of impedance change of a signal input to and output from a semiconductor package according to an example embodiment.

Referring to FIG. 10, a TDR device 600 may include a TDR module 400 and a measurement device 500. The TDR module 400 may include a step generator which may apply step pulses, and characteristic impedance Zs may be determined to be 50Ω. The measurement device 500 may be determined to have characteristic impedance Z0 of a transmission line, and the load impedance ZLoad may be determined to be 50Ω.

The TDR device 600 may track the amount of change in impedance by comparing the amount of the incident voltage wave with the amount of the reflected voltage wave. The TDR device 600 may go through changes in impedance when energy is incident from a transmitter to a transmission medium, and the reflected energy may return to the original transmitter. Accordingly, the amount of reflected energy may be proportional to the amount of transmitted energy and the changes in impedance.

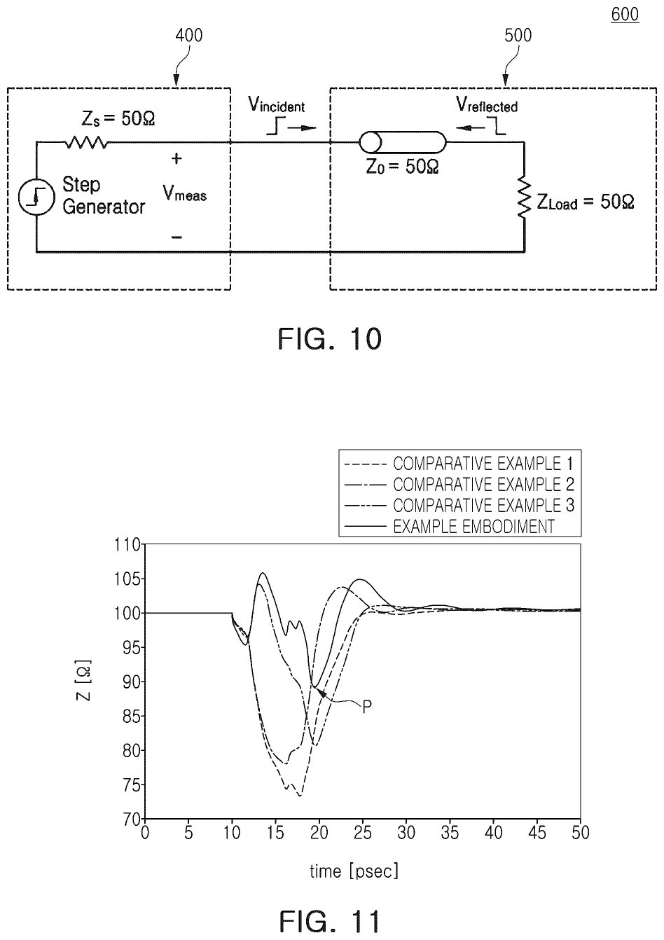

FIG. 11 is a diagram illustrating a TDR result of a signal input to and output from a semiconductor package according to an example embodiment. FIG. 11 may be a graph obtained by simulating the amount of impedance change of a signal input to and output from a transmission line passing through the second connection bumps 20 in the semiconductor package 1A in an example embodiment.

In FIG. 11, in comparative example 1, the first and second matching structures 125 and 225 were not applied. In comparative example 2, only the second matching structures 225 of the interposer die 200 were applied. In comparative example 3, only the first matching structures 125 of the package substrate 110 were applied.

Referring to FIG. 11, it is indicated that the TDR impedance Z in the example embodiment was greater than the TDR impedance Z of each of comparative example 1, comparative example 2, and comparative example 3 at the point “P.” As indicated above, when elements for impedance matching are disposed in both directions of the second connection bumps 20, the impedance matching effect of signals input to and output from the transmission line passing through the second connection bumps 20 may be improved.

According to the aforementioned example embodiments, by including the impedance matching structures above and below the connection bumps, which may cause impedance mismatching, a semiconductor package having improved integrity of an electrical signal may be provided.

While some example embodiments have been illustrated and described above, it will be configured as apparent to those skilled in the art that modifications and variations may be made to the disclosed example embodiments without departing from the scope as defined by the appended claims.

What is claimed is:

1. A semiconductor package, comprising:
a package substrate;
an interposer die on the package substrate;
semiconductor chips on the interposer die, the interposer die electrically connected to the package substrate via the interposer die;
first connection bumps electrically connecting the semiconductor chips to the interposer die;
second connection bumps electrically connecting the interposer die to the package substrate; and
third connection bumps disposed below the package substrate,
wherein the interposer die includes spiral matching structures adjacent to upper portions of the second connection bumps, and
wherein the package substrate includes trace-shaped matching structures adjacent to lower portions of the second connection bumps.

2. The semiconductor package of claim 1, wherein the spiral matching structures and the trace-shaped matching structures are configured to compensate for mismatching of impedance caused by the second connection bumps.

3. The semiconductor package of claim 1, wherein the spiral matching structures and the trace-shaped matching structures are configured to reduce signal delay.

4. The semiconductor package of claim 1, wherein the interposer die further includes lower pads in contact with the upper portions of the second connection bumps, and connection vias connecting the lower pads to the spiral matching structures.

5. The semiconductor package of claim 1, wherein each of the trace-shaped matching structures has one end electrically connected to the second connection bumps.

6. The semiconductor package of claim 5, wherein the package substrate further includes upper pads in contact with the lower portions of the second connection bumps, and connection vias connecting the upper pads to the one end of each of the trace-shaped matching structures.

7. The semiconductor package of claim 5, wherein the package substrate further includes upper pads in contact with the one end of each of the trace-shaped matching structures and the lower portions of the second connection bumps.

8. The semiconductor package of claim 5, wherein the package substrate further includes a wiring circuit in contact with the other end of each of the trace-shaped matching structures.

9. The semiconductor package of claim 5, wherein the package substrate further includes a wiring circuit below the trace-shaped matching structures and a connection via connecting the wiring circuit to the other end of each of the trace-shaped matching structures.

10. The semiconductor package of claim 1,
wherein the package substrate further includes a wiring circuit electrically connecting the second connection bumps to the third connection bumps, and
wherein the trace-shaped matching structures have a line width smaller than a line width of the wiring circuit.

11. The semiconductor package of claim 1, wherein each of the second connection bumps has a second width greater than a first width of each of the first connection bumps.

12. The semiconductor package of claim 11, wherein each of the third connection bumps has a third width greater than the second width of each of the second connection bumps.

13. The semiconductor package of claim 1,
wherein the semiconductor chips include a first semiconductor chip and a second semiconductor chip, the first semiconductor chip and the second semiconductor chip being side by side on the interposer die, and
wherein the interposer die further includes an upper connection circuit electrically connecting the first semiconductor chip to the second semiconductor chip.

14. The semiconductor package of claim 1,
wherein the semiconductor chips are vertically stacked on the interposer die,
wherein the interposer die includes a logic circuit, and
wherein the semiconductor chips include a memory circuit.

15. A semiconductor package, comprising:
a package substrate including trace-shaped matching structures and a wiring circuit, the trace-shaped matching structures being adjacent to an upper surface of the package substrate, the wiring circuit electrically connected to the trace-shaped matching structures;
an interposer die on the upper surface of the package substrate, the interposer die including spiral matching structures adjacent to a lower surface of the interposer die;
semiconductor chips on the interposer die;
first connection bumps electrically connecting the semiconductor chips to the interposer die; and
second connection bumps electrically connecting the spiral matching structures of the interposer die to the trace-shaped matching structures of the package substrate,
wherein a line width of each of the spiral matching structures is less than or equal to a line width of each of the trace-shaped matching structures, and
wherein a line width of each of the trace-shaped matching structures is smaller than a line width of the wiring circuit.

16. The semiconductor package of claim 15,
wherein a line width of each of the spiral matching structures is in a range of 1 μm to 10 μm, and
wherein a line width of each of the trace-shaped matching structures is in a range of 5 μm to 15 μm.

17. The semiconductor package of claim 15, wherein a line width of the wiring circuit is in a range of 20 μm to 100 μm.

18. A semiconductor package, comprising:
a package substrate including first matching structures and a wiring circuit electrically connected to the first matching structures;
an interposer die on the package substrate, the interposer die including second matching structures;
semiconductor chips on the interposer die;
first connection bumps electrically connecting the semiconductor chips to the interposer die; and
second connection bumps electrically connecting the first matching structures of the package substrate to the second matching structures of the interposer die,
wherein the first matching structures and the second matching structures have different shapes to compensate for mismatching of impedance caused by the second connection bumps.

19. The semiconductor package of claim 18, wherein each of the first matching structures has a trace shape having a line width smaller than a line width of the wiring circuit.

20. The semiconductor package of claim 18, wherein each of the second matching structures has a single layer or a multilayer spiral shape.
